(19) United States
(12) Patent Application Publication
(10) Pub. No.: US 2026/0182409 A1
(43) Pub. Date: Jun. 25, 2026

(54) PACKAGE COMPRISING SUBSTRATE WITH IMPROVED INDUCTOR ALIGNMENT AND/OR SPACING

(71) Applicant: QUALCOMM Incorporated, San Diego, CA (US)

(72) Inventors: Heun Gun SHIN, San Diego, CA (US); Kyudong KANG, Seoul (KR)

(21) Appl. No.: 18/990,125

(22) Filed: Dec. 20, 2024

(51) Int. Cl. H01L 23/498; H05K 1/11; H05K 1/16; H10D 1/20

(52) U.S. Cl. CPC H10W 70/65; H05K 1/115; H05K 1/165; H10D 1/20; H10W 70/685

(57) ABSTRACT

A substrate comprising at least one dielectric layer; a plurality of interconnects comprising: a first plurality of trace interconnects located on a first metal layer of the substrate, wherein the first plurality of trace interconnects are configured as one or more coils of a first inductor; and a second plurality of trace interconnects located on a second metal layer of the substrate, wherein the first plurality of trace interconnects are configured as one or more coils of a second inductor, at least one cavity in the at least one dielectric layer; and a solder resist layer located at least partially in the at least one cavity in the at least one dielectric layer.

### FIELD

Various features relate to packages with integrated devices and passive devices.

### BACKGROUND

A package may include a substrate and integrated devices. These components are coupled together to provide a package that may perform various electrical functions. There is an ongoing need to provide better performing packages. Moreover, there is also an ongoing need to reduce and/or minimize the overall size of the packages.

### SUMMARY

Various features relate to packages with integrated devices and passive devices.

One example provides a substrate comprising at least one dielectric layer; a plurality of interconnects comprising: a first plurality of trace interconnects located on a first metal layer of the substrate, wherein the first plurality of trace interconnects are configured as one or more coils of a first inductor; and a second plurality of trace interconnects located on a second metal layer of the substrate, wherein the first plurality of trace interconnects are configured as one or more coils of a second inductor, at least one cavity in the at least one dielectric layer; and a solder resist layer located at least partially in the at least one cavity in the at least one dielectric layer.

Another example provides a substrate comprising at least one dielectric layer; a plurality of interconnects comprising: a first plurality of trace interconnects located on a first metal layer of the substrate, wherein the first plurality of trace interconnects are configured as one or more coils of a first inductor; and a second plurality of trace interconnects located on a second metal layer of the substrate, wherein the first plurality of trace interconnects are configured as one or more coils of a second inductor, at least one cavity in the at least one dielectric layer; and another dielectric layer located at least partially in the at least one cavity in the at least one dielectric layer.

### BRIEF DESCRIPTION OF THE DRAWINGS

Various features, nature and advantages may become apparent from the detailed description set forth below when taken in conjunction with the drawings in which like reference characters identify correspondingly throughout.

FIG. 1 illustrates an exemplary cross sectional plan view of a substrate with inductors.

FIG. 2 illustrates an exemplary cross sectional plan view of a substrate with inductors.

FIG. 3 illustrates an exemplary cross sectional plan view of a substrate with inductors.

FIG. 4 illustrates an exemplary cross sectional plan view of a substrate with inductors.

FIG. 5 illustrates an exemplary cross sectional plan view of a substrate with inductors.

FIG. 6 illustrates an exemplary cross sectional profile view of a substrate with inductors.

FIG. 7 illustrates an exemplary cross sectional profile view of a substrate with inductors.

FIG. 8 illustrates an exemplary cross sectional profile view of a substrate with inductors.

FIG. 9 illustrates an exemplary cross sectional profile view of package comprising an integrated device and a substrate with inductors.

FIG. 10 illustrates an exemplary sequence for fabricating a substrate comprising inductors.

FIGS. 11A-11B illustrate an exemplary sequence for fabricating a substrate comprising inductors.

FIGS. 12A-12B illustrate an exemplary sequence for fabricating a substrate comprising inductors.

FIG. 13 illustrates an exemplary flow chart of a method for fabricating a substrate comprising inductors.

FIGS. 14A-14C illustrate an exemplary sequence for fabricating a substrate.

FIG. 15 illustrates an exemplary flow chart of a method for fabricating a substrate.

FIG. 16 illustrates various electronic devices that may integrate a die, an electronic circuit, an integrated device, an integrated passive device (IPD), a passive component, a package, and/or a device package described herein.

### DETAILED DESCRIPTION

In the following description, specific details are given to provide a thorough understanding of the various aspects of the disclosure. However, it will be understood by one of ordinary skill in the art that the aspects may be practiced without these specific details. For example, circuits may be shown as block diagrams in order to avoid obscuring the aspects in unnecessary detail. In other instances, well-known circuits, structures and techniques may not be shown in detail in order not to obscure the aspects of the disclosure.

The present disclosure describes a package comprising a substrate and an integrated device coupled to the substrate through at least a plurality of solder interconnects. The substrate comprises at least one dielectric layer; a plurality of interconnects comprising: a first plurality of trace interconnects located on a first metal layer of the substrate, wherein the first plurality of trace interconnects are configured as one or more coils of a first inductor; and a second plurality of trace interconnects located on a second metal layer of the substrate, wherein the first plurality of trace interconnects are configured as one or more coils of a second inductor, at least one cavity in the at least one dielectric layer; and a solder resist layer located at least partially in the at least one cavity in the at least one dielectric layer.

### Exemplary Package Comprising a Substrate With Inductors

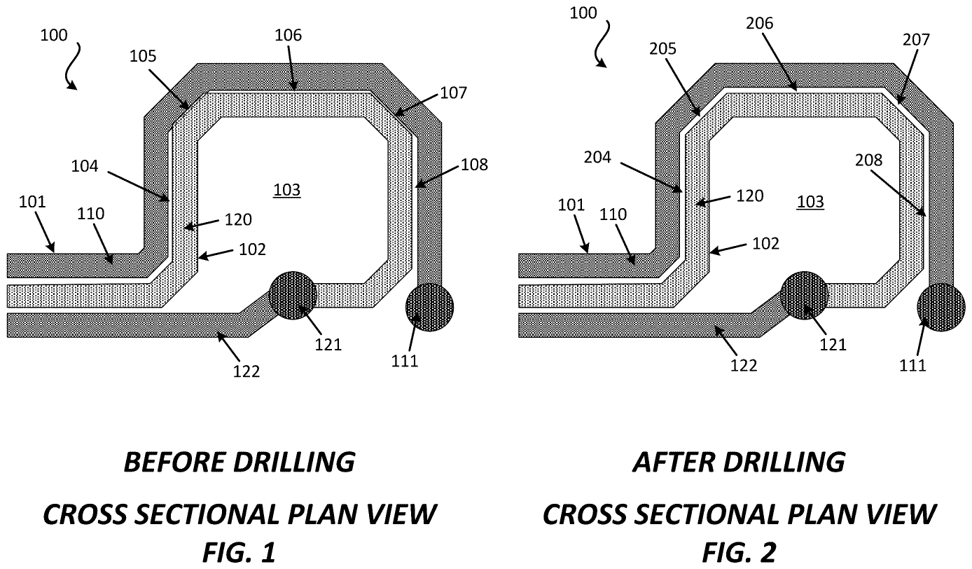

FIG. 1 illustrates an exemplary plan view of a substrate 100 that includes an inductor 101 (e.g., first inductor) and an inductor 102 (e.g., second inductor). A part of the inductor 101 may be located on a first metal layer of the substrate 100. A part of the inductor 102 may be located on a second metal layer of the substrate 100. The inductor 101 may be defined by at least one interconnect 110 (e.g., at least one trace interconnect). The at least one interconnect 110 is coupled to a pad interconnect 111. The inductor 102 may be defined by at least one interconnect 120 (e.g., at least one trace interconnect). The at least one interconnect 120 is coupled to a pad interconnect 121. An at least one interconnect 122 is coupled to the pad interconnect 121. The substrate 100 includes at least one dielectric layer 103.

FIG. 1 illustrates a spacing 104 (e.g., horizontal spacing) between the inductor 101 and the inductor 102. There is also a vertical overlap region 105 between the inductor 101 and the inductor 102. That is, a portion of the at least one interconnect 110 vertically overlaps with a portion of the at least one interconnect 120 in the vertical overlap region 105. There is a spacing 106 (e.g., horizontal spacing) between the inductor 101 and the inductor 102. There is a spacing 107 (e.g., horizontal spacing) between the inductor 101 and the inductor 102. There is a spacing 108 (e.g., horizontal spacing) between the inductor 101 and the inductor 102. FIG. 2 illustrates that the spacing 104, the spacing 106, the spacing 107 and the spacing 108 are different. The various spacings and/or the vertical overlap of the inductor 101 and the inductor 102 can lead to diminished inductor performance.

To provide more consistent spacing, reduce vertical overlap and/or minimize vertical overlap between inductors, drilling may be performed. FIG. 2 illustrate an exemplary plan view of the substrate 100 after drilling is performing around and/or nearby the inductor 101 and/or the inductor 102. The drilling may be performing with a laser. The laser drilling process may form cavities in the at least one dielectric layer 103 and may trim and/or remove portions of interconnects of the inductor 101 and/or portions of the inductor 102.

After drilling, a spacing 204 is formed between the inductor 101 and the inductor 102. The spacing 204 may be similar to the spacing 104 before drilling. After drilling, a spacing 205 is formed between the inductor 101 and the inductor 102. The spacing 205 replaces the vertical overlap region 105. Thus, an interconnect from the inductor 101 no longer vertically overlaps with an interconnect from the inductor 102 in that region. After drilling, a spacing 206 is formed between the inductor 101 and the inductor 102. The spacing 206 is greater than the spacing 106. After drilling, a spacing 206 is formed between the inductor 101 and the inductor 102. The spacing 207 is greater than the spacing 107. After drilling, a spacing 208 is formed between the inductor 101 and the inductor 102. The spacing 208 is about the same as the spacing 108. FIG. 2 illustrates that after drilling, the spacing 204, the spacing 205, the spacing 206, the spacing 207 and/or the spacing 208 are more uniform and/or consistent between different parts of the inductor 101 and the inductor 102. This can improve the overall of the inductor 101 and/or the inductor 102. It is noted that for purposes of clarity, the cavities in the at least one dielectric layer 103 are not shown in FIG. 1.

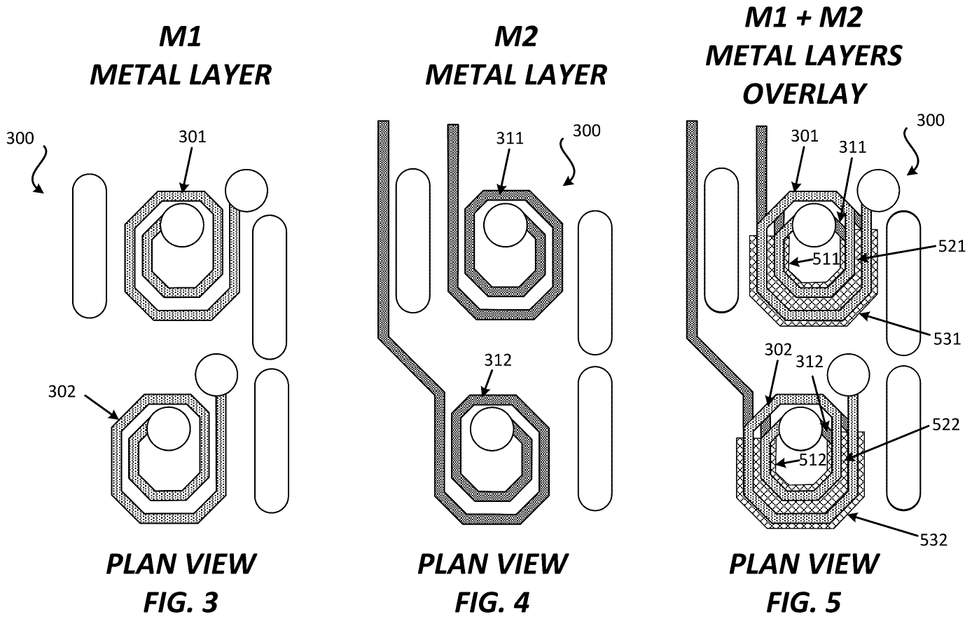

FIGS. 3-5 illustrates exemplary plan view of a substrate 300 with inductors. FIG. 3 illustrates a plan view of the substrate 300 with an inductor 301 and an inductor 302 that are located on a M1 metal layer of the substrate 300. The inductor 301 and the inductor 302 may be planar inductors. FIG. 4 illustrates a plan view of the substrate 300 with an inductor 311 and an inductor 312 that are located on a M2 metal layer of the substrate 300. The inductor 311 and the inductor 312 may be planar inductors. Each of the inductor 301, the inductor 302, the inductor 311 and the inductor 312 may include coils, windings, and/or turns, that are defined by one or more interconnects (e.g., trace interconnects) of the substrate 300.

FIG. 5 illustrates a plan view of the substrate 300 with an overlap of the M1 and M2 metal layers. As shown in FIG. 5, the inductor 301 vertically overlaps with inductor 311, and the inductor 302 vertically overlaps with the inductor 312. To provide uniform spacing between coils, windings and/or turns of inductors, and uniform spacing between vertically overlapping inductors, a drilling process may be formed in the region 511, the region 521, the region 531, the region 512, the region 522 and/or the region 532. The drilling may be a laser drilling process (e.g., laser ablation) that forms cavities in the dielectric layer of the substrate 300 and may remove and/or trims portions of interconnects of the inductor 301, portions of interconnects of the inductor 302, portions of interconnects of the inductor 311 and/or portions of interconnects of the inductor 312. The drilling process may be performed in one or more regions between coils, windings, turns of inductors. It is noted that the region 511, the region 521, the region 531, the region 512, the region 522 and/or the region 532 are exemplary. The drilling process may be performed in other portions of the substrate 300. It is further noted that each of the region 511, the region 521, the region 531, the region 512, the region 522 and/or the region 532, may represent one or more separate regions. For example, the region 511 may represent multiple separate regions.

The drilling process may result in edges of interconnects from one inductor to vertically align with edges of interconnects of another inductor on a different metal layer. For example, a first edge of a first interconnect (e.g., first trace interconnect) from the inductor 311 may vertically align with a first edge of a first interconnect (e.g., first trace interconnect) from the inductor 301. In some implementations, a second edge of a second interconnect (e.g., second trace interconnect) from the inductor 311 may vertically align with a second edge of a second interconnect (e.g., second trace interconnect) from the inductor 301. In some implementations, a third edge of a third interconnect (e.g., third trace interconnect) from the inductor 311 may vertically align with a third edge of a third interconnect (e.g., third trace interconnect) from the inductor 301.

In some implementations, (i) a first edge of a first interconnect (e.g., first trace interconnect) from the inductor 311 may vertically align with a first edge of a first interconnect (e.g., first trace interconnect) from the inductor 301 and (ii) a second edge of the first interconnect (e.g., first trace interconnect) from the inductor 311 may vertically align with a second edge of the first interconnect (e.g., first trace interconnect) from the inductor 301, where the second edge is opposite to the first edge. In some implementations, (i) a first edge of a second interconnect (e.g., second trace interconnect) from the inductor 311 may vertically align with a first edge of a second interconnect (e.g., second trace interconnect) from the inductor 301 and (ii) a second edge of the second interconnect (e.g., second trace interconnect) from the inductor 311 may vertically align with a second edge of the second interconnect (e.g., second trace interconnect) from the inductor 301, where the second edge is opposite to the first edge.

In some implementations, a first edge of a first interconnect from the inductor 312 may vertically align with a first edge of a first interconnect from the inductor 302. In some implementations, a second edge of a second interconnect from the inductor 312 may vertically align with a second edge of a second interconnect from the inductor 302. In some implementations, a third edge of a third interconnect from the inductor 312 may vertically align with a third edge of a third interconnect from the inductor 302.

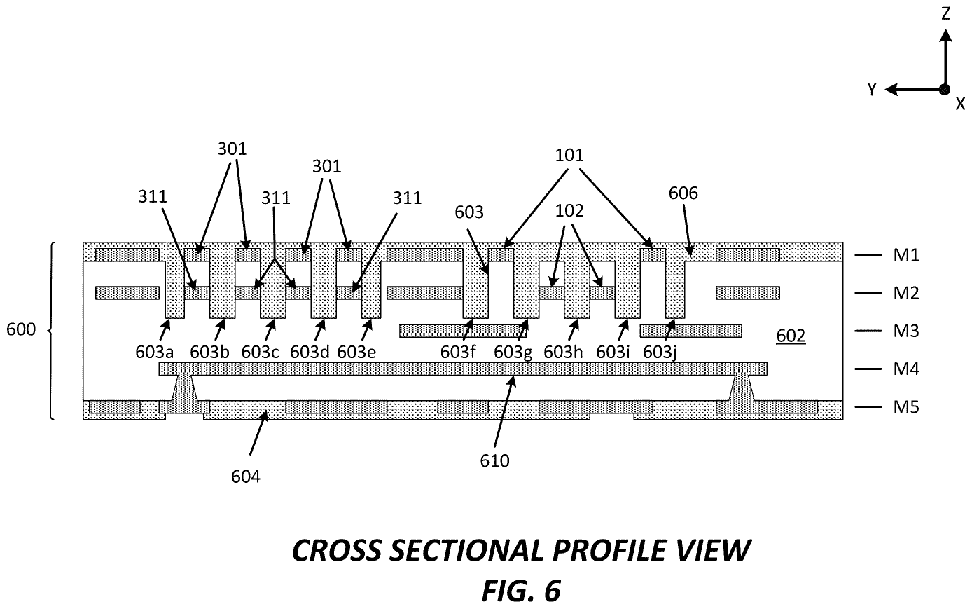

FIG. 6 illustrates an exemplary cross sectional profile view of a substrate 600. The substrate 600 includes at least one dielectric layer 602, a plurality of cavities 603, a plurality of interconnects 610, a solder resist layer 604 and a solder resist layer 606. The substrate 600 includes an inductor 101, an inductor 102, and inductor 301 and an inductor 311. The substrate 600 may be a laminate substrate.

The inductor 101 may be defined from interconnects from the plurality of interconnects 610. The inductor 101 may be located on the M1 metal layer of the substrate 600. The inductor 102 may be defined from interconnects from the plurality of interconnects 610. The inductor 101 may be located on the M2 metal layer of the substrate 600. The inductor 301 may be defined from interconnects from the plurality of interconnects 610. The inductor 301 may be located on the M1 metal layer of the substrate 600. The inductor 311 may be defined from interconnects from the plurality of interconnects 610. The inductor 311 may be located on the M2 metal layer of the substrate 600. However, it is noted that the inductors may be located on other metal layers of the substrate 600. In some implementations, an edge of an interconnect of an inductor that vertically aligns with an edge of another interconnect of another inductor means that the edges are within about 1 micrometers of vertical alignment of each other.

The plurality of cavities 603 may include a cavity 603a, a cavity 603b, a cavity 603c, a cavity 603d, a cavity 603e, a cavity 603f, a cavity 603g, a cavity 603h, a cavity 603i and a cavity 603j. The plurality of cavities 603 may extend in the at least one dielectric layer 602, through the M1 metal layer and the M2 metal layer. However, the plurality of cavities 603 may have different depths. For example, the plurality of cavities 603 may have a depth that is about 30 micrometers beyond the M2 metal layer. The plurality of cavities 603 help provide unform spacing between the coils, windings and/or turns of the inductor 301, the inductor 311, the inductor 101 and/or the inductor 102. In some implementations the plurality of cavities 603 may help eliminate and/or reduce vertical overlap with interconnects of different inductors (e.g., help eliminate and/or reduce vertical overlap with interconnects of inductor 101 and inductor 102). In some implementations, the minimum spacing (e.g., minimum horizontal spacing) between interconnects of an inductor is 35 micrometers. In some implementations, the minimum spacing (e.g., minimum horizontal spacing) between interconnects of two different inductors is 35 micrometers. In some implementations, one or more cavity from the plurality of cavities 603 may have a width of about 35 micrometers. The lower minimum horizontal spacing is possible because interconnects can be fabricated closer and subsequently trimmed by the laser drilling process. Without the laser drilling process, the minimum horizontal spacing between interconnects would have to be much higher due to account and/or adjust for the limitations and/or drawbacks in the fabrication process, such as shifting, which can cause adjacent interconnects to touch and/or cause interconnects to vertically overlap. Smaller spacing and/or smaller widths for interconnects means that the substrate and/or the package can be smaller, and thus these substrates and/or packages can be implemented in smaller devices.

FIG. 6 illustrates an example of edges of interconnects from one inductor to vertically align with another inductor on a different metal layer. For example, a first edge of a first interconnect from the inductor 311 may vertically align with a first edge of a first interconnect from the inductor 301. In some implementations, a second edge of a second interconnect from the inductor 311 may vertically align with a second edge of a second interconnect from the inductor 301. In some implementations, a third edge of a third interconnect from the inductor 311 may vertically align with a third edge of a third interconnect from the inductor 301.

A solder resist layer 604 is formed and coupled to a surface (e.g., bottom surface) of the at least one dielectric layer 602. A solder resist layer 606 may be formed and coupled to a surface (e.g., top surface) of the at least one dielectric layer 602. The solder resist layer 606 may be located at least partially in the plurality of cavities 603. The solder resist layer 606 may be located laterally to the M1 metal layer and the M2 metal layer. The solder resist layer 606 may be located laterally to the inductor 301, the inductor 311, the inductor 101, and the inductor 102. It is noted that the plurality of cavities 603 may still be considered cavities in the substrate 600, even if the plurality of cavities 603 are at least partially filled and/or occupied by a material.

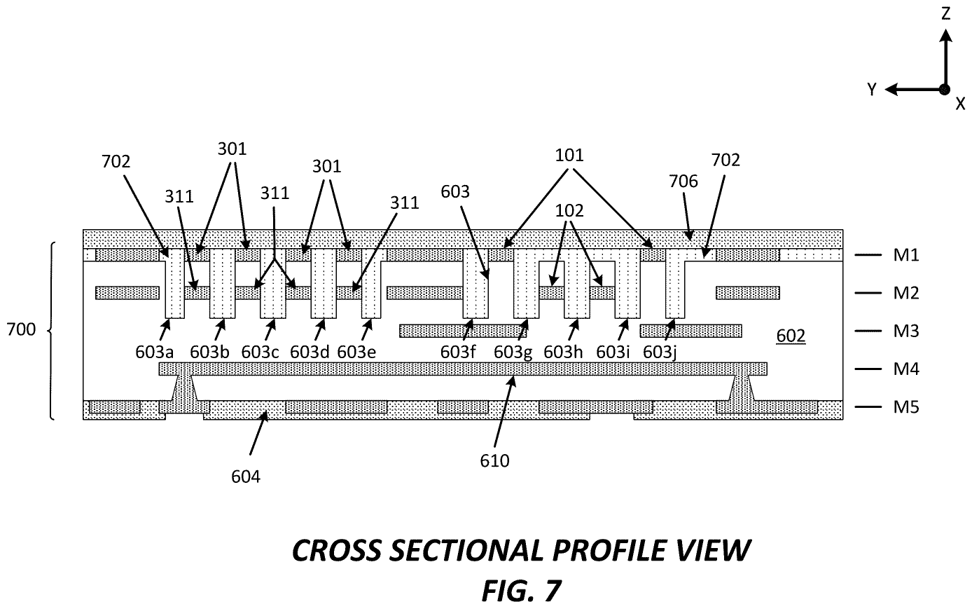

FIG. 7 illustrates an exemplary cross sectional profile view of a substrate 700. The substrate 700 includes at least one dielectric layer 602, a plurality of cavities 603, a dielectric layer 702, a plurality of interconnects 610, a solder resist layer 604 and a solder resist layer 606. The substrate 700 includes an inductor 101, an inductor 102, and inductor 301 and an inductor 311. The substrate 700 is similar to the substrate 600, and may be configured and/or arranged in a similar manner as described for the substrate 600.

FIG. 7 illustrates a dielectric layer 702 that is located at least partially in the plurality of cavities 603. The dielectric layer 702 may include the same material or a different material from the at least one dielectric layer 602. In some implementations, the at least one dielectric layer 602 may include prepreg. In some implementations, the dielectric layer 702 may include prepreg and/or an epoxy. The dielectric layer 702 may be located laterally to the M1 metal layer and the M2 metal layer. The dielectric layer 702 may be located laterally to the inductor 301, the inductor 311, the inductor 101, and the inductor 102. It is noted that the plurality of cavities 603 may still be considered cavities in the substrate 700, even if the plurality of cavities 603 is at least partially filled and/or occupied by a material (e.g., dielectric material). The solder resist layer 706 is coupled to the dielectric layer 702. The substrate 700 may be a laminate substrate.

FIG. 7 illustrates an example of edges of interconnects from one inductor to vertically align with another inductor on a different metal layer. For example, a first edge of a first interconnect from the inductor 311 may vertically align with a first edge of a first interconnect from the inductor 301. In some implementations, a second edge of a second interconnect from the inductor 311 may vertically align with a second edge of a second interconnect from the inductor 301. In some implementations, a third edge of a third interconnect from the inductor 311 may vertically align with a third edge of a third interconnect from the inductor 301.

FIGS. 6 and 7 illustrates the inductor 301 and the inductor 101 are located at least partially on the M1 metal layer of a substrate, and the inductor 311 and the inductor 102 are located at least partially on the M2 metal layer of a substrate. However, the inductors may be located on different metal layers of a substrate.

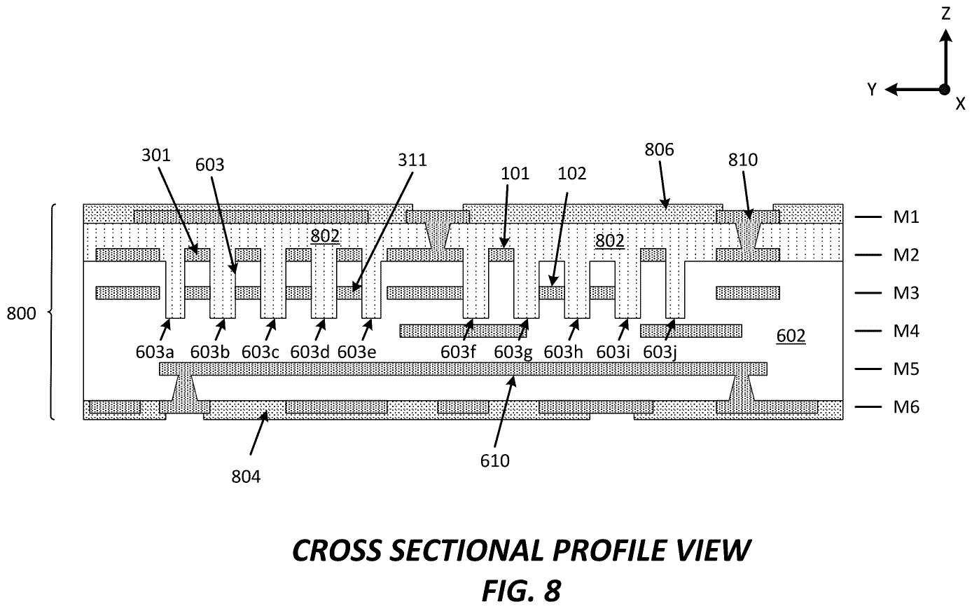

FIG. 8 illustrates an exemplary cross sectional profile view of a substrate 800. The substrate 800 includes at least one dielectric layer 602, a plurality of cavities 603, a dielectric layer 802, a plurality of interconnects 610, a plurality of interconnects 810, a solder resist layer 804 and a solder resist layer 6806. The substrate 800 includes an inductor 101, an inductor 102, and inductor 301 and an inductor 311. The substrate 800 is similar to the substrate 700 and/or the substrate 600, and may be configured and/or arranged in a similar manner as described for the substrate 700 and/or the substrate 600. The substrate 800 may be a laminate substrate.

FIG. 8 illustrates a dielectric layer 802 that is located at least partially in the plurality of cavities 603. The dielectric layer 802 may include the same material or a different material from the at least one dielectric layer 602. In some implementations, the at least one dielectric layer 602 may include prepreg. In some implementations, the dielectric layer 802 may include prepreg and/or an epoxy. The dielectric layer 802 may be located laterally to the M2 metal layer and the M3 metal layer. The dielectric layer 802 may be located laterally to the inductor 301, the inductor 311, the inductor 101, and the inductor 102. It is noted that the plurality of cavities 603 may still be considered cavities in the substrate 800, even if the plurality of cavities 603 are at least partially filled and/or occupied by a material (e.g., dielectric material). The solder resist layer 806 is coupled to the dielectric layer 802. The plurality of interconnects 810 may be located in and/or over the dielectric layer 802.

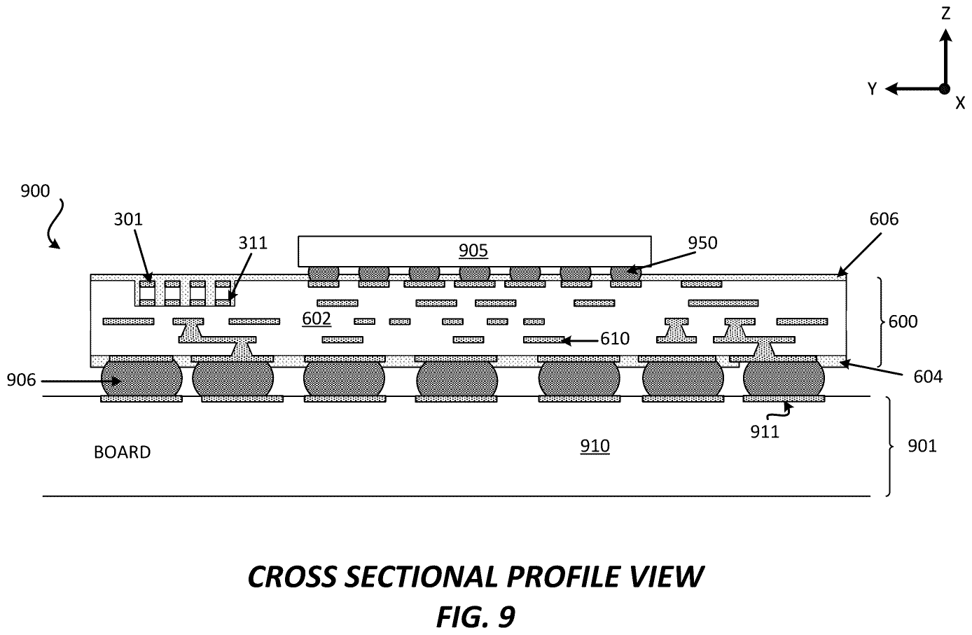

FIG. 9 illustrates a cross sectional profile view of a package 900 that includes integrated devices. The package 900 is coupled to a board 901 through a plurality of solder interconnects 906. The board 901 includes at least one board dielectric layer 910 and a plurality of board interconnects 911. The board 901 may include a printed circuit board (PCB). In some implementations, the package 900 may be coupled to a substrate instead of the board 901.

The package 900 includes a substrate 600 and an integrated device 905. The integrated device 905 is coupled to the substrate 600 through a plurality of solder interconnects 950. The substrate 600 includes at least one dielectric layer 602, a plurality of interconnects 610, a solder resist layer 604 and a solder resist layer 606. The substrate 600 also includes an inductor 301 and an inductor 311. The inductor 301 and/or the inductor 311 may be defined from interconnects from the plurality of interconnects 610. The substrate 600 includes a plurality of cavities 603 located around and/or adjacent to the inductor 301 and the inductor 311. The plurality of cavities 603 may extend through the at least one dielectric layer 602. The solder resist layer 606 may be located in the plurality of cavities 603. In some implementations, the package 900 may include the substrate 700 or the substrate 800 instead of the substrate 600.

An integrated device (e.g., 905) may include a die (e.g., semiconductor bare die). The integrated device may include a power management integrated circuit (PMIC). The integrated device may include an application processor. The integrated device may include a modem. The integrated device may include a radio frequency (RF) device, a passive device, a filter, a capacitor, an inductor, an antenna, a transmitter, a receiver, a gallium arsenide (GaAs) based integrated device, a surface acoustic wave (SAW) filter, a bulk acoustic wave (BAW) filter, a light emitting diode (LED) integrated device, a silicon (Si) based integrated device, a silicon carbide (SiC) based integrated device, a memory, power management processor, and/or combinations thereof. An integrated device may include at least one electronic circuit (e.g., first electronic circuit, second electronic circuit, etc . . . ). An integrated device may include an input/output (I/O) hub. An integrated device may include transistors. An integrated device may be an example of an electrical component and/or electrical device.

In some implementations, an integrated device may be a chiplet. A chiplet may be fabricated using a process that provides better yields compared to other processes used to fabricate other types of integrated devices, which can lower the overall cost of fabricating a chiplet. Different chiplets may have different sizes and/or shapes. Different chiplets may be configured to provide different functions. Different chiplets may have different interconnect densities (e.g., interconnects with different width and/or spacing). In some implementations, several chiplets may be used to perform the functionalities of one or more chips (e.g., one more integrated devices). As mentioned above, using several chiplets that perform several functions may reduce the overall cost of a package relative to using a single chip to perform all of the functions of a package. In some implementations, one or more of the chiplets and/or one of more of integrated devices (e.g., 905) described in the disclosure may be fabricated using the same technology node or two or more different technology nodes. For example, an integrated device may be fabricated using a first technology node, and a chiplet may be fabricated using a second technology node that is not as advanced as the first technology node. In such an example, the integrated device may include components (e.g., interconnects, transistors) that have a first minimum size, and the chiplet may include components (e.g., interconnects, transistors) that have a second minimum size, where the second minimum size is greater than the first minimum size. In some implementations, a first integrated device and a second integrated device of a package, may be fabricated using the same technology node or different technology nodes. In some implementations, a chiplet and another chiplet of a package, may be fabricated using the same technology node or different technology nodes.

A technology node may refer to a specific fabrication process and/or technology that is used to fabricate an integrated device and/or a chiplet. A technology node may specify the smallest possible size (e.g., minimum size) that can be fabricated (e.g., size of a transistor, width of trace, gap width between two transistors). Different technology nodes may have different yield loss. Different technology nodes may have different costs. Technology nodes that produce components (e.g., trace, transistors) with fine details are more expensive and may have higher yield loss, than a technology node that produces components (e.g., trace, transistors) with details that are less fine. Thus, more advanced technology nodes may be more expensive and may have higher yield loss, than less advanced technology nodes. When all of the functions of a package are implemented in single integrated devices, the same technology node is used to fabricate the entire integrated device, even if some of the functions of the integrated devices do not need to be fabricated using that particular technology node. Thus, the integrated device is locked into one technology node. To optimize the cost of a package, some of the functions can be implemented in different integrated devices and/or chiplets, where different integrated devices and/or chiplets may be fabricated using different technology nodes to reduce overall costs. For example, functions that require the use of the most advanced technology node may be implemented in an integrated device, and functions that can be implemented using a less advanced technology node can be implemented in another integrated device and/or one or more chiplets. One example, would be an integrated device, fabricated using a first technology node (e.g., most advanced technology node), that is configured to provide compute applications, and at least one chiplet, that is fabricated using a second technology node, that is configured to provide other functionalities, where the second technology node is not as costly as the first technology node, and where the second technology node fabricates components with minimum sizes that are greater than the minimum sizes of components fabricated using the first technology node. Examples of compute applications may include high performance computing and/or high performance processing, which may be achieved by fabricating and packing in as many transistors as possible in an integrated device, which is why an integrated device that is configured for compute applications may be fabricated using the most advanced technology node available, while other chiplets may be fabricated using less advanced technology nodes, since those chiplets may not require as many transistors to be fabricated in the chiplets. Thus, the combination of using different technology nodes (which may have different associated yield loss) for different integrated devices and/or chiplets, can reduce the overall cost of a package, compared to using a single integrated device to perform all the functions of the package.

Another advantage of splitting the functions into several integrated devices and/or chiplets, is that it allows improvements in the performance of the package without having to redesign every single integrated device and/or chiplet. For example, if a configuration of a package uses a first integrated device and a first chiplet, it may be possible to improve the performance of the package by changing the design of the first integrated device, while keeping the design of the first chiplet the same. Thus, the first chiplet could be reused with the improved and/or different configured first integrated device. This saves cost by not having to redesign the first chiplet, when packages with improved integrated devices are fabricated.

The package (e.g., 900) may be implemented in a radio frequency (RF) package. The RF package may be a radio frequency front end (RFFE) package. A package (e.g., 900) may be configured to provide Wireless Fidelity (WiFi) communication and/or cellular communication (e.g., 2G, 3G, 4G, 5G, 6G). The packages (e.g., 900) may be configured to support Global System for Mobile (GSM) Communications, Universal Mobile Telecommunications System (UMTS), and/or Long-Term Evolution (LTE). The packages (e.g., 900) may be configured to transmit and receive signals having different frequencies and/or communication protocols.

### Exemplary Sequence for Fabricating a Substrate

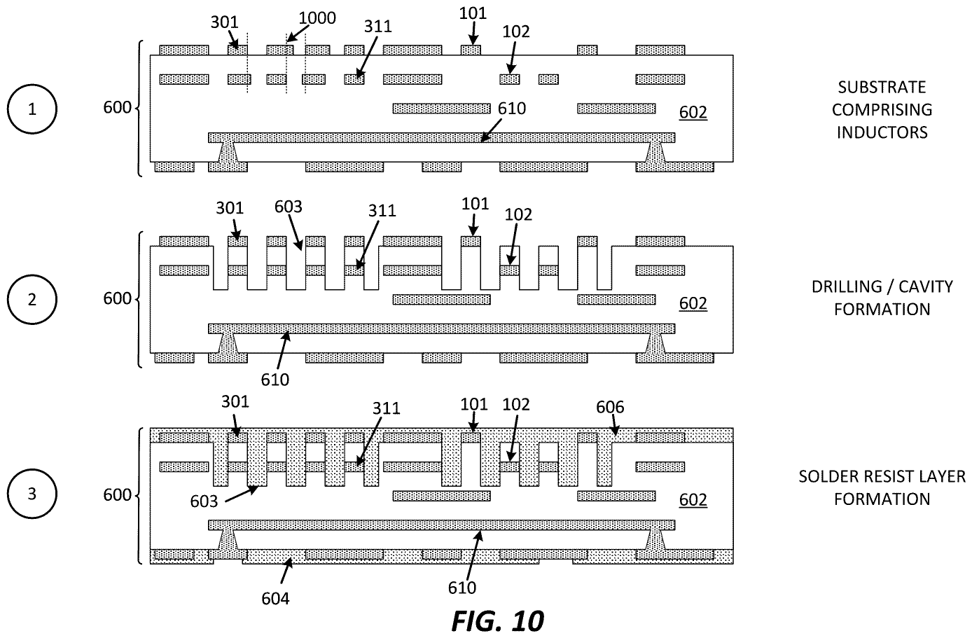

In some implementations, fabricating a substrate includes several processes. FIG. 10 illustrates an exemplary sequence for providing or fabricating a substrate. In some implementations, the sequence of FIG. 10 may be used to provide or fabricate the substrate 600. However, the process of FIG. 10 may be used to fabricate any of the substrates described in the disclosure.

It should be noted that the sequence of FIG. 10 may combine one or more stages in order to simplify and/or clarify the sequence for providing or fabricating a substrate. In some implementations, the order of the processes may be changed or modified. In some implementations, one or more of processes may be replaced or substituted without departing from the scope of the disclosure.

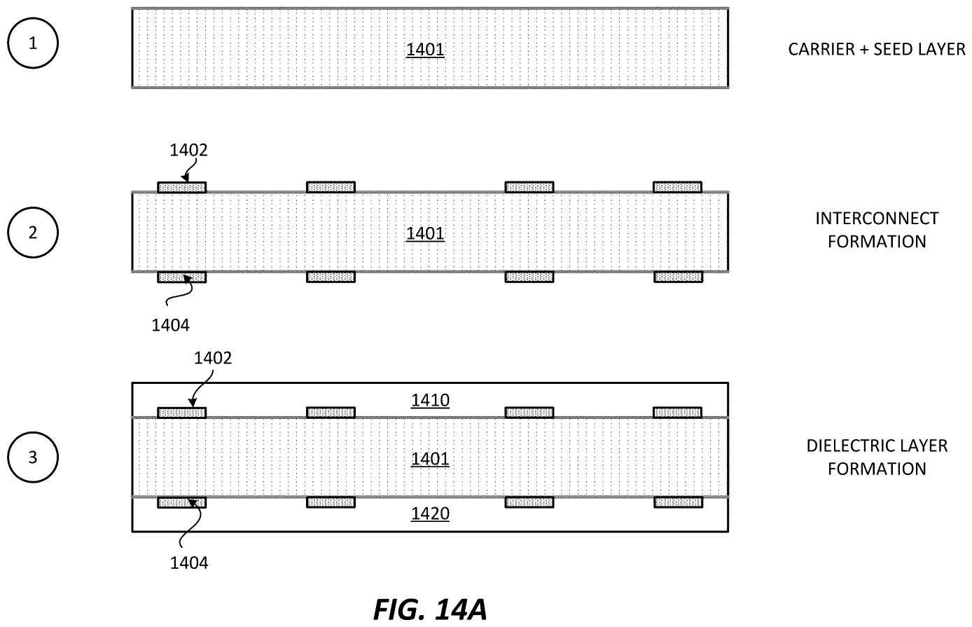

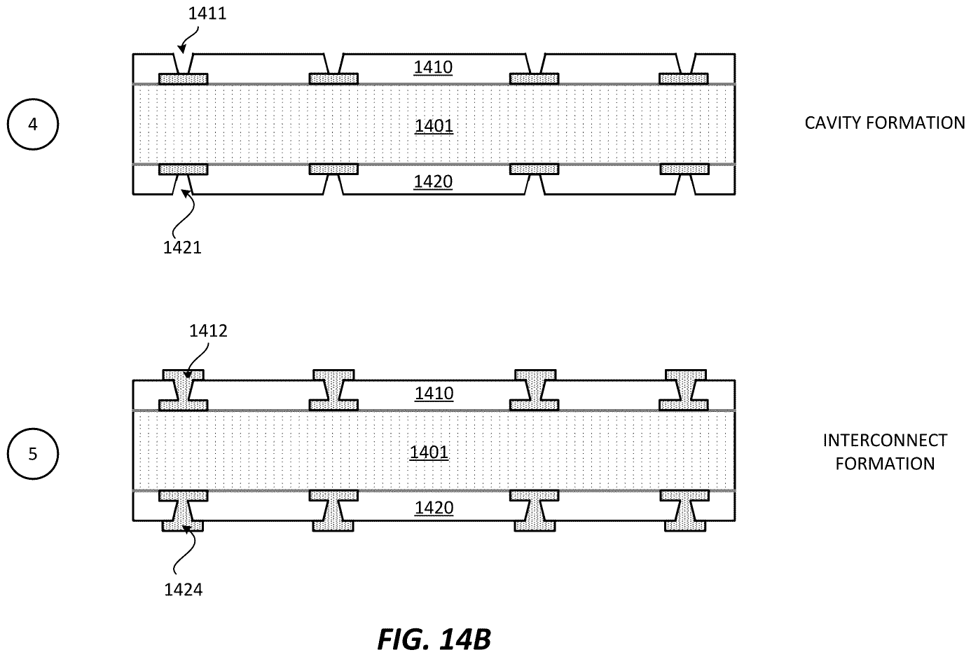

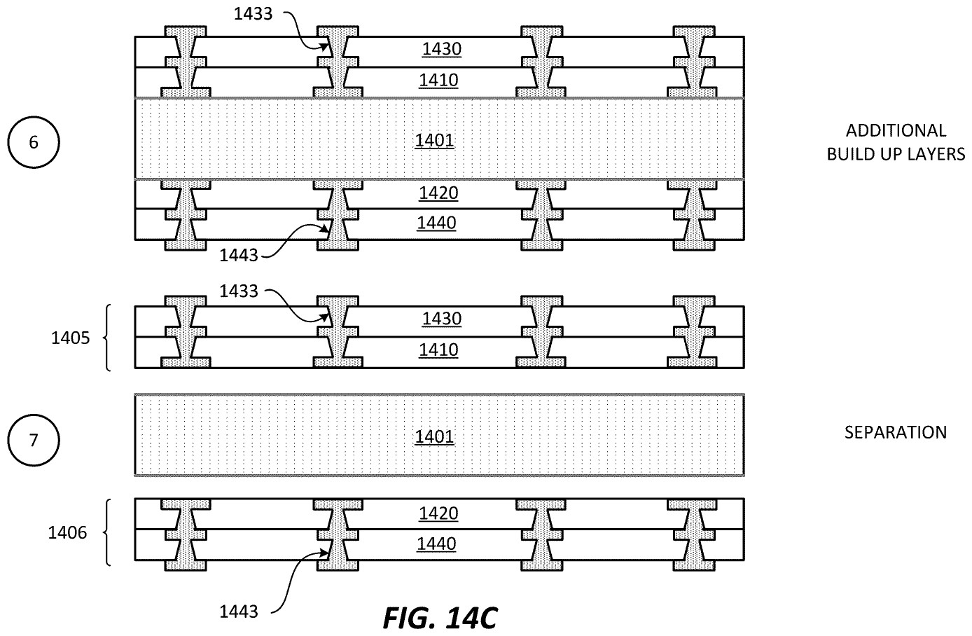

Stage 1, as shown in FIG. 10, illustrates a state after a substrate 600 is provided and/or fabricated. The substrate 600 includes at least one dielectric layer 602 and a plurality of interconnects 610. The substrate 600 may include an inductor 101, and inductor 102, an inductor 301 and a inductor 311. Each of these inductors may be defined from interconnects from the plurality of interconnects 610. An example of a process for fabricating a substrate is illustrated and described below in at least FIGS. 14A-14C. Stage 1 illustrates that due to limitations of the fabrication process of the substrate 600, some of the edges from the inductor 301 may not vertically align with edges from the inductor 311 (which is conceptually illustrated by the conceptual dashed lines 1000 between interconnects of the inductor 301 and interconnects of the inductor 311).

Stage 2 illustrates a state after a drilling of the substrate 600. The drilling of the substrate 600 may be a laser drilling process that forms a plurality of cavities 603 in the at least one dielectric layer 602. The laser drilling process may also trim and/or remove portions of the inductor 101, portions of the inductor 102, portions of the inductor 301 and/or portions of the inductor 311. That is, portions of the interconnects that define an inductor may be removed during the drilling process. In some implementations, the drilling process may form cavities that have a minimum width of about 35 micrometers. Moreover, in some implementations, the drilling process may form spacing (e.g., horizontal spacing) between coils, windings and/or turns of an inductor, that are about 35 micrometers. In some implementations, the drilling process may form spacing (e.g., horizontal spacing) between coils, windings and/or turns of two inductors, that are about 35 micrometers. The drill process may form cavities that extend beyond the first metal layer and the second metal layer of the substrate 600.

Stage 3 illustrates a state after a solder resist layer 604 and a solder resist layer 606 are provided and formed. A deposition process and/or a lamination process may be used to form the solder resist layer 604 and/or the solder resist layer 606. The solder resist layer 604 may be coupled to a bottom surface of the at least one dielectric layer 602. The solder resist layer 606 may be formed and coupled to a top surface of the at least one dielectric layer 602. The solder resist layer 606 may be formed at least partially in the plurality of cavities 603. The solder resist layer 606 may include a different material from the at least one dielectric layer 602.

### Exemplary Sequence for Fabricating a Substrate

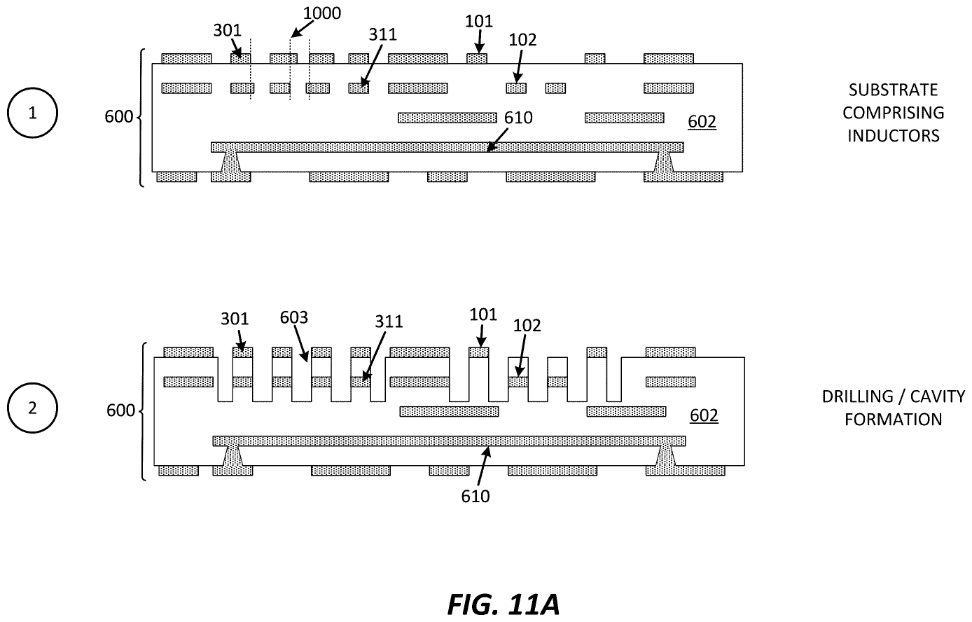

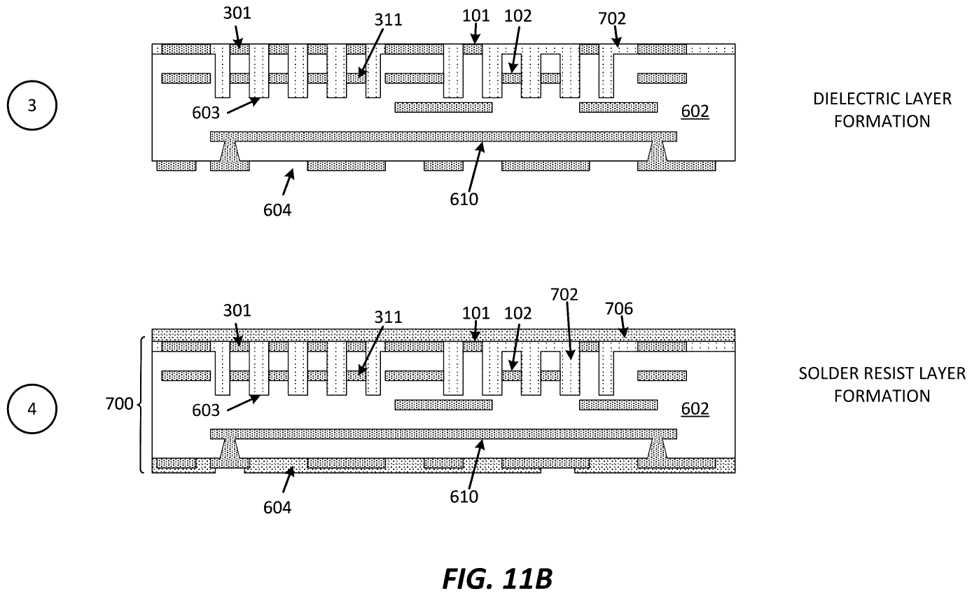

In some implementations, fabricating a substrate includes several processes. FIGS. 11A-11B illustrate an exemplary sequence for providing or fabricating a substrate. In some implementations, the sequence of FIGS. 11A-11B illustrate may be used to provide or fabricate the substrate 700. However, the process of FIGS. 11A-11B may be used to fabricate any of the substrates described in the disclosure.

It should be noted that the sequence of FIGS. 11A-11B may combine one or more stages in order to simplify and/or clarify the sequence for providing or fabricating a substrate. In some implementations, the order of the processes may be changed or modified. In some implementations, one or more of processes may be replaced or substituted without departing from the scope of the disclosure.

Stage 1, as shown in FIG. 11A, illustrates a state after a substrate 600 is provided and/or fabricated. The substrate 600 includes at least one dielectric layer 602 and a plurality of interconnects 610. The substrate 600 may include an inductor 101, and inductor 102, an inductor 301 and a inductor 311. Each of these inductors may be defined from interconnects from the plurality of interconnects 610. An example of a process for fabricating a substrate is illustrated and described below in at least FIGS. 14A-14C. Stage 1 illustrates that due to limitations of the fabrication process of the substrate 600, some of the edges from the inductor 301 may not vertically align with edges from the inductor 311 (which is conceptually illustrated by the conceptual dashed lines 1000 between interconnects of the inductor 301 and interconnects of the inductor 311).

Stage 2 illustrates a state after a drilling of the substrate 600. The drilling of the substrate 600 may be a laser drilling process that forms a plurality of cavities 603 in the at least one dielectric layer 602. The laser drilling process may also trim and/or remove portions of the inductor 101, portions of the inductor 102, portions of the inductor 301 and/or portions of the inductor 311. That is, portions of the interconnects that define an inductor may be removed during the drilling process. In some implementations, the drilling process may form cavities that have a minimum width of about 35 micrometers. Moreover, in some implementations, the drilling process may form spacing (e.g., horizontal spacing) between coils, windings and/or turns of an inductor, that are about 35 micrometers. In some implementations, the drilling process may form spacing (e.g., horizontal spacing) between coils, windings and/or turns of two inductors, that are about 35 micrometers. The drill process may form cavities that extend beyond the first metal layer and the second metal layer of the substrate 600.

Stage 3, as shown in FIG. 11B, illustrates a state after a dielectric layer 702 is provided and formed. A deposition process and/or a lamination process may be used to form the dielectric layer 702. The dielectric layer 702 may be formed at least partially in the plurality of cavities 603. The dielectric layer 702 may include a different material from the at least one dielectric layer 602. The dielectric layer 702 may include a same material as the at least one dielectric layer 602. In some implementations, the at least one dielectric layer 602 may include prepreg. In some implementations, the dielectric layer 702 may include prepreg and/or epoxy. There may or may not be a boundary interface layer between the at least one dielectric layer 602 and the dielectric layer 702. Such a boundary interface layer may be present even if the at least one dielectric layer 602 and the dielectric layer 702 include the same material. In some implementations, the dielectric layer 702 may be considered part of the at least one dielectric layer 602.

Stage 4 illustrates a state after a solder resist layer 704 and a solder resist layer 706 are provided and formed. A deposition process and/or a lamination process may be used to form the solder resist layer 704 and/or the solder resist layer 706. The solder resist layer 704 may be coupled to a bottom surface of the at least one dielectric layer 602. The solder resist layer 706 may be formed and coupled to a top surface of the dielectric layer 702. The solder resist layer 706 may include a different material from the at least one dielectric layer 602 and/or the dielectric layer 702.

### Exemplary Sequence for Fabricating a Substrate

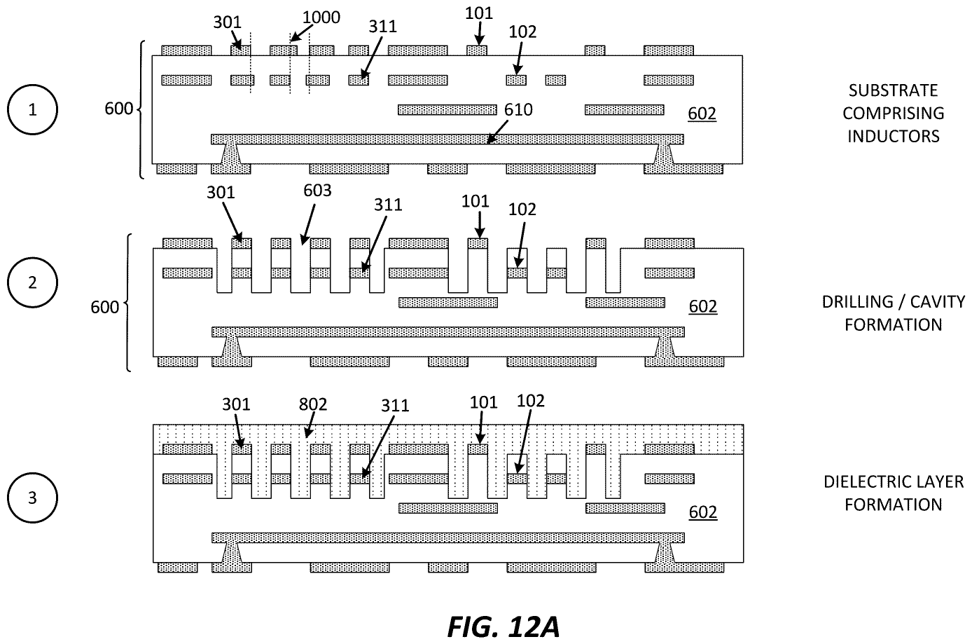

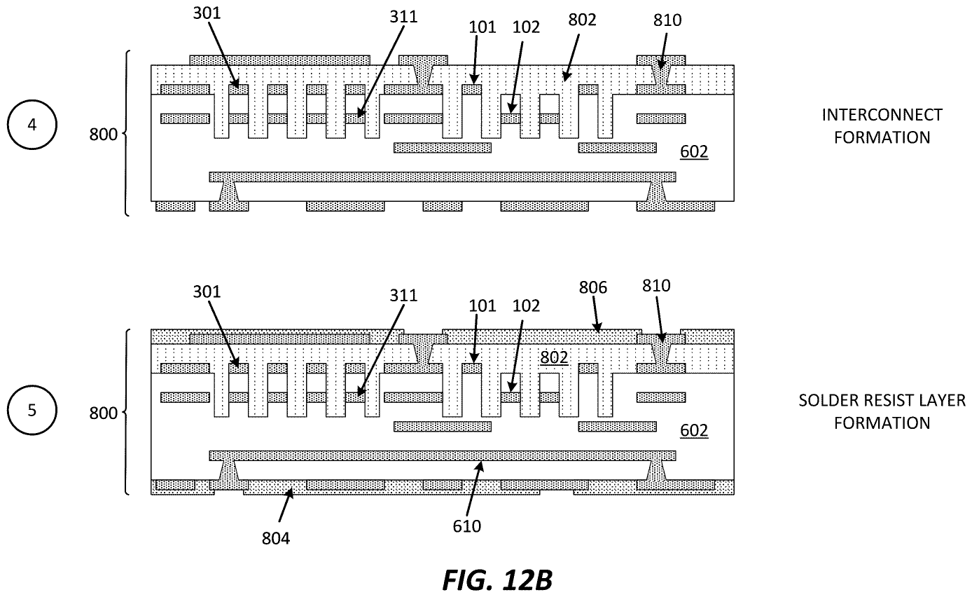

In some implementations, fabricating a substrate includes several processes. FIGS. 12A-12B illustrate an exemplary sequence for providing or fabricating a substrate. In some implementations, the sequence of FIGS. 12A-12B illustrate may be used to provide or fabricate the substrate 800. However, the process of FIGS. 12A-12B may be used to fabricate any of the substrates described in the disclosure.

It should be noted that the sequence of FIGS. 12A-12B may combine one or more stages in order to simplify and/or clarify the sequence for providing or fabricating a substrate. In some implementations, the order of the processes may be changed or modified. In some implementations, one or more of processes may be replaced or substituted without departing from the scope of the disclosure.

Stage 1, as shown in FIG. 12A, illustrates a state after a substrate 600 is provided and/or fabricated. The substrate 600 includes at least one dielectric layer 602 and a plurality of interconnects 610. The substrate 600 may include an inductor 101, and inductor 102, an inductor 301 and a inductor 311. Each of these inductors may be defined from interconnects from the plurality of interconnects 610. An example of a process for fabricating a substrate is illustrated and described below in at least FIGS. 14A-14C. Stage 1 illustrates that due to limitations of the fabrication process of the substrate 600, some of the edges from the inductor 301 may not vertically align with edges from the inductor 311 (which is conceptually illustrated by the conceptual dashed lines 1000 between interconnects of the inductor 301 and interconnects of the inductor 311).

Stage 2 illustrates a state after a drilling of the substrate 600. The drilling of the substrate 600 may be a laser drilling process that forms a plurality of cavities 603 in the at least one dielectric layer 602. The laser drilling process may also trim and/or remove portions of the inductor 101, portions of the inductor 102, portions of the inductor 301 and/or portions of the inductor 311. That is, portions of the interconnects that define an inductor may be removed during the drilling process. In some implementations, the drilling process may form cavities that have a minimum width of about 35 micrometers. Moreover, in some implementations, the drilling process may form spacing (e.g., horizontal spacing) between coils, windings and/or turns of an inductor, that are about 35 micrometers. In some implementations, the drilling process may form spacing (e.g., horizontal spacing) between coils, windings and/or turns of two inductors, that are about 35 micrometers. The drill process may form cavities that extend beyond the first metal layer and the second metal layer of the substrate 600.

Stage 3 illustrates a state after a dielectric layer 802 is provided and formed. A deposition process and/or a lamination process may be used to form the dielectric layer 802. The dielectric layer 802 may be formed at least partially in the plurality of cavities 603. The dielectric layer 802 may include a different material from the at least one dielectric layer 602. The dielectric layer 802 may include a same material as the at least one dielectric layer 602. In some implementations, the at least one dielectric layer 602 may include prepreg. In some implementations, the dielectric layer 802 may include prepreg and/or epoxy. There may or may not be a boundary interface layer between the at least one dielectric layer 602 and the dielectric layer 802. Such a boundary interface layer may be present even if the at least one dielectric layer 602 and the dielectric layer 802 include the same material. In some implementations, the dielectric layer 802 may be considered part of the at least one dielectric layer 602.

Stage 4, as shown in FIG. 12B, illustrates a state after a plurality of interconnects 810 are formed in and above the dielectric layer 802. The dielectric layer 802 and the plurality of interconnects 810 may be build up layers for the substrate. A lamination process, an exposure process, a development process, a plating process, a strip process, and/or an etching process may be used to form the plurality of interconnects 810. The plurality of interconnects 810 are coupled to the plurality of interconnects 610.

Stage 5 illustrates a state after a solder resist layer 704 and a solder resist layer 706 are provided and formed. A deposition process and/or a lamination process may be used to form the solder resist layer 704 and/or the solder resist layer 706. The solder resist layer 704 may be coupled to a bottom surface of the at least one dielectric layer 602. The solder resist layer 706 may be formed and coupled to a top surface of the dielectric layer 802. The solder resist layer 806 may include a different material from the at least one dielectric layer 602 and/or the dielectric layer 802.

### Exemplary Flow Diagram of a Method for Fabricating a Substrate

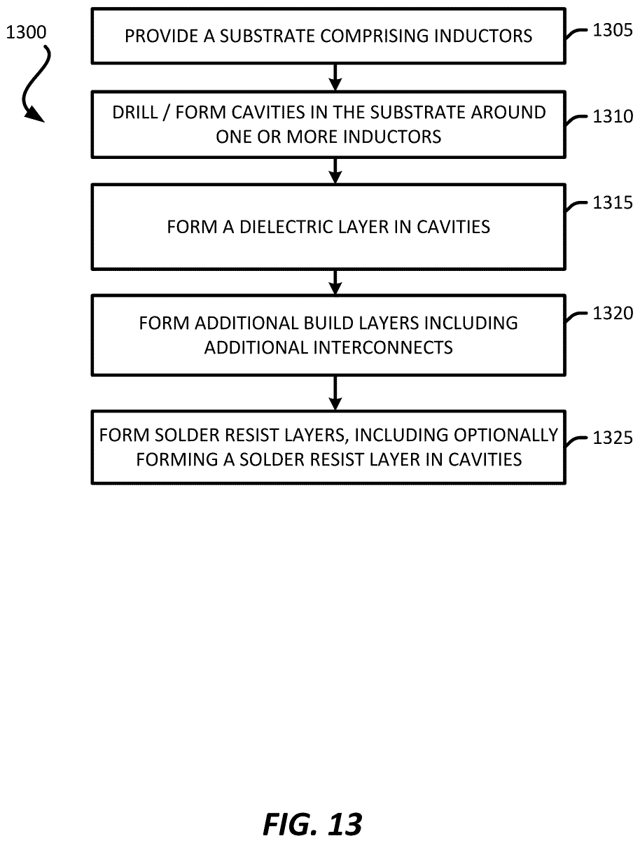

In some implementations, fabricating a substrate includes several processes. FIG. 13 illustrates an exemplary flow diagram of a method 1300 for providing or fabricating a substrate that includes an interposer. In some implementations, the method 1300 of FIG. 13 may be used to provide or fabricate the substrate 800 described in the disclosure. However, the method 1300 may be used to provide or fabricate any of the substrates described in the disclosure.

It should be noted that the method 1300 of FIG. 13 may combine one or more processes in order to simplify and/or clarify the method for providing or fabricating a substrate. In some implementations, the order of the processes may be changed or modified.

The method provides (at 1305) a substrate comprising inductors. Stage 1 of FIG. 12A, illustrates and describes an example of a state after a substrate 600 is provided and/or fabricated. The substrate 600 includes at least one dielectric layer 602 and a plurality of interconnects 610. The substrate 600 may include an inductor 101, and inductor 102, an inductor 301 and a inductor 311. Each of these inductors may be defined from interconnects from the plurality of interconnects 610. An example of a process for fabricating a substrate is illustrated and described below in at least FIGS. 14A-14C.

The method forms (at 1310) a plurality of cavities in the dielectric layer of the substrate, through a drilling process. The cavities may be formed around inductors in the substrate. The drilling process may remove portions of one or more inductors. Stage 2 of FIG. 12A, illustrates and describes an example of a state after a drilling of the substrate 600. The drilling of the substrate 600 may be a laser drilling process that forms a plurality of cavities 603 in the at least one dielectric layer 602. The laser drilling process may also trim and/or remove portions of the inductor 101, portions of the inductor 102, portions of the inductor 301 and/or portions of the inductor 311. That is, portions of the interconnects that define an inductor may be removed during the drilling process. In some implementations, the drilling process may form cavities that have a minimum width of about 35 micrometers. Moreover, in some implementations, the drilling process may form spacing (e.g., horizontal spacing) between coils, windings and/or turns of an inductor, that are about 35 micrometers. In some implementations, the drilling process may form spacing (e.g., horizontal spacing) between coils, windings and/or turns of two inductors, that are about 35 micrometers. The drill process may form cavities that extend beyond the first metal layer and the second metal layer of the substrate 600.

The method forms (at 1315) a dielectric layer in the plurality of cavities. Stage 3 of FIG. 12A, illustrates and describes an example of a state after a dielectric layer 802 is provided and formed. A deposition process and/or a lamination process may be used to form the dielectric layer 802. The dielectric layer 802 may be formed at least partially in the plurality of cavities 603. The dielectric layer 802 may include a different material from the at least one dielectric layer 602. The dielectric layer 802 may include a same material as the at least one dielectric layer 602. In some implementations, the at least one dielectric layer 602 may include prepreg. In some implementations, the dielectric layer 802 may include prepreg and/or epoxy. There may or may not be a boundary interface layer between the at least one dielectric layer 602 and the dielectric layer 802. Such a boundary interface layer may be present even if the at least one dielectric layer 602 and the dielectric layer 802 include the same material. In some implementations, the dielectric layer 802 may be considered part of the at least one dielectric layer 602.

The method forms (at 1320) additional build up layers, which may include form additional dielectric layers and/or additional interconnects for the substrate. Stage 4 of FIG. 12B, illustrates and describes an example of a state after a plurality of interconnects 810 are formed in and above the dielectric layer 802. The dielectric layer 802 and the plurality of interconnects 810 may be build up layers for the substrate. A lamination process, an exposure process, a development process, a plating process, a strip process, and/or an etching process may be used to form the plurality of interconnects 810. The plurality of interconnects 810 are coupled to the plurality of interconnects 610.

The method forms (at 1325) solder resist layers to the substrate. Stage 5 of FIG. 12B, illustrates and describes an example of a state after a solder resist layer 704 and a solder resist layer 706 are provided and formed. A deposition process and/or a lamination process may be used to form the solder resist layer 704 and/or the solder resist layer 706. The solder resist layer 704 may be coupled to a bottom surface of the at least one dielectric layer 602. The solder resist layer 706 may be formed and coupled to a top surface of the dielectric layer 802. The solder resist layer 806 may include a different material from the at least one dielectric layer 602 and/or the dielectric layer 802.

In some implementations, the solder resist layer may be formed in the plurality of cavities of the substrate. This may be the case when no additional dielectric layer and/or no additional interconnects are formed. Stage 3 of FIG. 10, illustrates and describes an example of a solder resist that is formed in a plurality of cavities of a dielectric layer 602.

### Exemplary Sequence for Fabricating a Substrate

In some implementations, fabricating a substrate includes several processes. FIGS. 14A-14C illustrate an exemplary sequence for providing or fabricating a substrate. In some implementations, the sequence of FIGS. 14A-14C may be used to provide or fabricate a laminate substrate. For example, the sequence of FIGS. 14A-14C may be used to provide or fabricate a laminate substrate.

It should be noted that the sequence of FIGS. 14A-14C may combine one or more stages in order to simplify and/or clarify the sequence for providing or fabricating a substrate. In some implementations, the order of the processes may be changed or modified. In some implementations, one or more of processes may be replaced or substituted without departing from the scope of the disclosure.

Stage 1, as shown in FIG. 14A, illustrates a state after a carrier 1401 is provided. The carrier 1401 may include a core layer. The core layer may include seed layers on surfaces of the core layer.

Stage 2 illustrates a state after a plurality of interconnects 1402 and a plurality of interconnects 1404 are formed. The plurality of interconnects 1402 may be coupled to a first surface (e.g., top surface) of the carrier 1401. The plurality of interconnects 1404 may be coupled to a second surface (e.g., bottom surface) of the carrier 1401. A plating process may be used to form the plurality of interconnects 1402 and the plurality of interconnects 1404. The plurality of interconnects 1402 may be formed on a first seed layer of the carrier 1401. The plurality of interconnects 1404 may be formed on a second seed layer of the carrier 1401.

Stage 3 illustrates a state after a dielectric layer 1410 and a dielectric layer 1420 are provided. The dielectric layer 1410 may be coupled to the first surface of the carrier 1401. The dielectric layer 1420 may be coupled to the second surface of the carrier 1401. A deposition and/or a lamination process may be used to form the dielectric layer 1410 and/or the dielectric layer 1420. The dielectric layer 1410 and/or the dielectric layer 1420 may include prepreg, polymer and/or Ajinomoto Build-up Film (ABF).

Stage 4 of FIG. 14B, illustrates a state after a plurality of cavities 1411 are formed in the dielectric layer 1410, and a plurality of cavities 1421 are formed in the dielectric layer 1420. An exposure and development process may be used to form the plurality of cavities 1411 in the dielectric layer 1410 and the plurality of cavities 1421 in the dielectric layer 1420. Different implementations may use different processes to form the plurality of cavities.

Stage 5 illustrates a state after a plurality of interconnects 1412 are formed in the dielectric layer 1410, and a plurality of interconnects 1424 are formed in the dielectric layer 1420. The plurality of interconnects 1412 may be coupled to the plurality of interconnects 1402. The plurality of interconnects 1424 may be coupled to the plurality of interconnects 1404. A plating process may be used to form the plurality of interconnects 1412 and/or the plurality of interconnects 1424.

Stage 6, as shown in FIG. 14C, illustrates a state after additional build up layers are formed. For example, stage 6 illustrates a state after additional dielectric layers and additional interconnects are formed. For example, a dielectric layer 1430 may be formed and coupled to the dielectric layer 1410. A dielectric layer 1440 may be formed and coupled to the dielectric layer 1420. A lamination process and/or a deposition process may be used to form the dielectric layer 1430 and the dielectric layer 1440.

Stage 6 further illustrates a state after a plurality of interconnects 1433 are formed in and over the dielectric layer 1430, and after a plurality of interconnects 1443 are formed in and over the dielectric layer 1440. The plurality of interconnects 1433 may be coupled to the plurality of interconnects 1412. The plurality of interconnects 1443 may be coupled to the plurality of interconnects 1424. A plurality of cavities may be formed in the dielectric layer 1430 and the dielectric layer 1440 in a similar manner as described for forming a plurality of cavities in Stage 4 of FIG. 14B. The plurality of interconnects 1433 and the plurality of interconnects 1443 may be formed in a similar manner as described for fabricating a plurality of interconnects in Stage 5 of FIG. 14B.

Stage 7 illustrates a state after separation of the dielectric layers from the carrier 1401. For example, the dielectric layer 1410, the dielectric layer 1430, the plurality of interconnects 1402, the plurality of interconnects 1412 and the plurality of interconnects 1433 are separated from the carrier 1401 to form a substrate 1405 (e.g., coreless substrate). In another example, the dielectric layer 1420, the dielectric layer 1440, the plurality of interconnects 1404, the plurality of interconnects 1424 and the plurality of interconnects 1443 are separated from the carrier 1401 to form a substrate 1406 (e.g., coreless substrate).

In some implementations, once separation occurs, one or more solder resist layers may be formed on surface(s) of the substrate 1405 and/or the substrate 1406.

### Exemplary Flow Diagram of a Method for Fabricating a Substrate

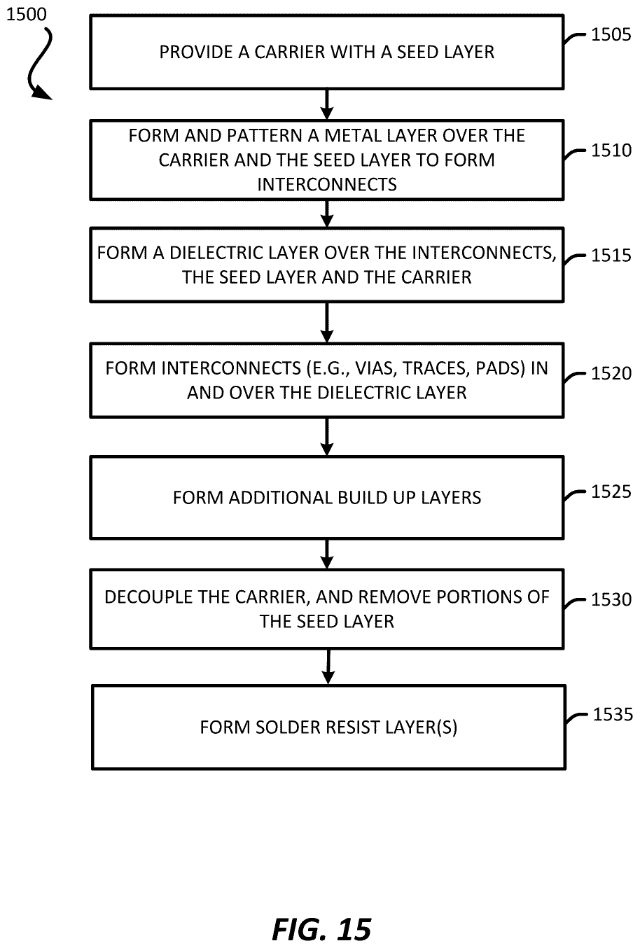

In some implementations, fabricating an substrate includes several processes. FIG. 15 illustrates an exemplary flow diagram of a method 1500 for providing or fabricating a substrate. In some implementations, the method 1500 of FIG. 15 may be used to provide or fabricate a laminate substrate.

It should be noted that the method 1500 of FIG. 15 may combine one or more processes in order to simplify and/or clarify the method for providing or fabricating a substrate. In some implementations, the order of the processes may be changed or modified.

The method provides (at 1505) a carrier. The carrier may include seed layers. Stage 1 of FIG. 14A, illustrates and describes an example of a state after a carrier 1401 is provided. The carrier 1401 may include a core layer. The core layer may include seed layers on surfaces of the core layer.

The method forms (at 1510) a plurality of interconnects on the carrier and/or the seed layer(s). Stage 2 of FIG. 14A, illustrates and describes an example of a state after a plurality of interconnects 1402 and a plurality of interconnects 1404 are formed. The plurality of interconnects 1402 may be coupled to a first surface (e.g., top surface) of the carrier 1401. The plurality of interconnects 1404 may be coupled to a second surface (e.g., bottom surface) of the carrier 1401. A plating process may be used to form the plurality of interconnects 1402 and the plurality of interconnects 1404. The plurality of interconnects 1402 may be formed on a first seed layer of the carrier 1401. The plurality of interconnects 1404 may be formed on a second seed layer of the carrier 1401.

The method forms (at 1515) at least one dielectric layer over the plurality of interconnects, the seed layer(s) and/or the carrier. Stage 3 of FIG. 14A, illustrates and describes an example of a state after a dielectric layer 1410 and a dielectric layer 1420 are provided. The dielectric layer 1410 may be coupled to the first surface of the carrier 1401. The dielectric layer 1420 may be coupled to the second surface of the carrier 1401. A deposition and/or a lamination process may be used to form the dielectric layer 1410 and/or the dielectric layer 1420. The dielectric layer 1410 and/or the dielectric layer 1420 may include prepreg, polymer and/or Ajinomoto Build-up Film (ABF).

Forming the plurality of interconnects may include forming a plurality of cavities in the dielectric layer(s). Stage 4 of FIG. 14B, illustrates and describes an example of a state after a plurality of cavities 1411 are formed in the dielectric layer 1410, and a plurality of cavities 1421 are formed in the dielectric layer 1420. An exposure and development process may be used to form the plurality of cavities 1411 in the dielectric layer 1410 and the plurality of cavities 1421 in the dielectric layer 1420. Different implementations may use different processes to form the plurality of cavities.

Stage 5 of FIG. 14B, illustrates and describes an example of a state after a plurality of interconnects 1412 are formed in the dielectric layer 1410, and a plurality of interconnects 1424 are formed in the dielectric layer 1420. The plurality of interconnects 1412 may be coupled to the plurality of interconnects 1402. The plurality of interconnects 1424 may be coupled to the plurality of interconnects 1404. A plating process may be used to form the plurality of interconnects 1412 and/or the plurality of interconnects 1424.

The method forms (at 1525) additional build up layers. Stage 6 of FIG. 14C, illustrates and describes an example of a state after additional build up layers are formed. For example, stage 6 illustrates a state after additional dielectric layers and additional interconnects are formed. For example, a dielectric layer 1430 may be formed and coupled to the dielectric layer 1410. A dielectric layer 1440 may be formed and coupled to the dielectric layer 1420. A lamination process and/or a deposition process may be used to form the dielectric layer 1430 and the dielectric layer 1440.

Stage 6 of FIG. 14C, further illustrates and describes an example of a state after a plurality of interconnects 1433 are formed in and over the dielectric layer 1430, and after a plurality of interconnects 1443 are formed in and over the dielectric layer 1440. The plurality of interconnects 1433 may be coupled to the plurality of interconnects 1412. The plurality of interconnects 1443 may be coupled to the plurality of interconnects 1424. A plurality of cavities may be formed in the dielectric layer 1430 and the dielectric layer 1440 in a similar manner as described for forming a plurality of cavities in Stage 4 of FIG. 14B. The plurality of interconnects 1433 and the plurality of interconnects 1443 may be formed in a similar manner as described for fabricating a plurality of interconnects in Stage 5 of FIG. 14B.

The method decouples (at 1530) the carrier from the dielectric layers. The method may further remove portions of the seed layer(s). Stage 7 of FIG. 14C, illustrates and describes an example of a state after separation of the dielectric layers from the carrier 1401. For example, the dielectric layer 1410, the dielectric layer 1430, the plurality of interconnects 1402, the plurality of interconnects 1412 and the plurality of interconnects 1433 are separated from the carrier 1401 to form a substrate 1405 (e.g., coreless substrate). In another example, the dielectric layer 1420, the dielectric layer 1440, the plurality of interconnects 1404, the plurality of interconnects 1424 and the plurality of interconnects 1443 are separated from the carrier 1401 to form a substrate 1406 (e.g., coreless substrate).

The method may further form (at 1535) solder resist layer(s) on the substrate. In some implementations, once separation occurs, one or more solder resist layers may be formed on surface(s) of the substrate 1405 and/or the substrate 1406.

### Exemplary Electronic Devices

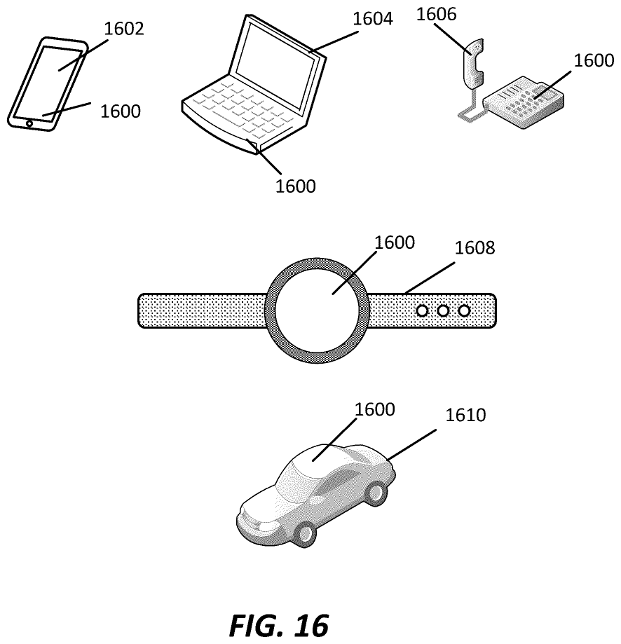

FIG. 16 illustrates various electronic devices that may be integrated with any of the aforementioned device, integrated device, integrated circuit (IC) package, integrated circuit (IC) device, semiconductor device, integrated circuit, die, interposer, package, package-on-package (PoP), System in Package (SiP), or System on Chip (SoC). For example, a mobile phone device 1602, a laptop computer device 1604, a fixed location terminal device 1606, a wearable device 1608, or automotive vehicle 1610 may include a device 1600 as described herein. The device 1600 may be, for example, any of the devices and/or integrated circuit (IC) packages described herein. The devices 1602, 1604, 1606 and 1608 and the vehicle 1610 illustrated in FIG. 16 are merely exemplary. Other electronic devices may also feature the device 1600 including, but not limited to, a group of devices (e.g., electronic devices) that includes mobile devices, hand-held personal communication systems (PCS) units, portable data units such as personal digital assistants, global positioning system (GPS) enabled devices, navigation devices, set top boxes, music players, video players, entertainment units, fixed location data units such as meter reading equipment, communications devices, smartphones, tablet computers, computers, wearable devices (e.g., watches, glasses), Internet of things (IoT) devices, servers, routers, electronic devices implemented in automotive vehicles (e.g., autonomous vehicles), or any other device that stores or retrieves data or computer instructions, or any combination thereof.

One or more of the components, processes, features, and/or functions illustrated in FIGS. 1-10, 11A-11B, 12A-12B, 13, 14A-14B, and 15-16 may be rearranged and/or combined into a single component, process, feature or function or embodied in several components, processes, or functions. Additional elements, components, processes, and/or functions may also be added without departing from the disclosure. It should also be noted FIGS. 1-10, 11A-11B, 12A-12B, 13, 14A-14B, and 15-16 and its corresponding description in the present disclosure is not limited to dies and/or ICs. In some implementations, FIGS. 1-10, 11A-11B, 12A-12B, 13, 14A-14B, and 15-16 and its corresponding description may be used to manufacture, create, provide, and/or produce devices and/or integrated devices. In some implementations, a device may include a die, an integrated device, an integrated passive device (IPD), a die package, an integrated circuit (IC) device, a device package, an integrated circuit (IC) package, a wafer, a semiconductor device, a package-on-package (PoP) device, a heat dissipating device and/or an interposer.

It is noted that the figures in the disclosure may represent actual representations and/or conceptual representations of various parts, components, objects, devices, packages, integrated devices, integrated circuits, and/or transistors. In some instances, the figures may not be to scale. In some instances, for purpose of clarity, not all components and/or parts may be shown. In some instances, the position, the location, the sizes, and/or the shapes of various parts and/or components in the figures may be exemplary. In some implementations, various components and/or parts in the figures may be optional.

The word “exemplary” is used herein to mean “serving as an example, instance, or illustration.” Any implementation or aspect described herein as “exemplary” is not necessarily to be construed as preferred or advantageous over other aspects of the disclosure. Likewise, the term “aspects” does not require that all aspects of the disclosure include the discussed feature, advantage or mode of operation. The term “coupled” is used herein to refer to the direct or indirect coupling (e.g., mechanical coupling) between two objects. For example, if object A physically touches object B, and object B touches object C, then objects A and C may still be considered coupled to one another—even if they do not directly physically touch each other. An object A, that is coupled to an object B, may be coupled to at least part of object B. The term “electrically coupled” may mean that two objects are directly or indirectly coupled together such that an electrical current (e.g., signal, power, ground) may travel between the two objects. Two objects that are electrically coupled may or may not have an electrical current traveling between the two objects. The use of the terms “first”, “second”, “third” and “fourth” (and/or anything above fourth) is arbitrary. Any of the components described may be the first component, the second component, the third component or the fourth component. For example, a component that is referred to a second component, may be the first component, the second component, the third component or the fourth component. The terms “encapsulate”, “encapsulating” and/or any derivation means that the object may partially encapsulate or completely encapsulate another object. The terms “top” and “bottom” are arbitrary. A component that is located on top may be located over a component that is located on a bottom. A top component may be considered a bottom component, and vice versa. As described in the disclosure, a first component that is located “over” a second component may mean that the first component is located above or below the second component, depending on how a bottom or top is arbitrarily defined. In another example, a first component may be located over (e.g., above) a first surface of the second component, and a third component may be located over (e.g., below) a second surface of the second component, where the second surface is opposite to the first surface. It is further noted that the term “over” as used in the present application in the context of one component located over another component, may be used to mean a component that is on another component and/or in another component (e.g., on a surface of a component or embedded in a component). Thus, for example, a first component that is over the second component may mean that (1) the first component is over the second component, but not directly touching the second component, (2) the first component is on (e.g., on a surface of) the second component, and/or (3) the first component is in (e.g., embedded in) the second component. A first component that is located “in” a second component may be partially located in the second component or completely located in the second component. A value that is about X-XX, may mean a value that is between X and XX, inclusive of X and XX. The value(s) between X and XX may be discrete or continuous. The term “about ‘value X’”, or “approximately value X”, as used in the disclosure means within 10 percent of the ‘value X’. For example, a value of about 1 or approximately 1, would mean a value in a range of 0.9-1.1. A “plurality” of components may include all the possible components or only some of the components from all of the possible components. For example, if a device includes ten components, the use of the term “the plurality of components” may refer to all ten components or only some of the components from the ten components.

In some implementations, an interconnect is an element or component of a device or package that allows or facilitates an electrical connection between two points, elements and/or components. In some implementations, an interconnect may include a trace (e.g., trace interconnect), a via (e.g., via interconnect), a pad (e.g., pad interconnect), a pillar, a metallization layer, a redistribution layer, and/or an under bump metallization (UBM) layer/interconnect. In some implementations, an interconnect may include an electrically conductive material that may be configured to provide an electrical path for a signal (e.g., a data signal), ground and/or power. An interconnect may include more than one element or component. An interconnect may be defined by one or more interconnects. An interconnect may include one or more metal layers. An interconnect may be part of a circuit. Different implementations may use different processes and/or sequences for forming the interconnects. In some implementations, a chemical vapor deposition (CVD) process, a physical vapor deposition (PVD) process, a sputtering process, a spray coating, and/or a plating process may be used to form the interconnects.

Also, it is noted that various disclosures contained herein may be described as a process that is depicted as a flowchart, a flow diagram, a structure diagram, or a block diagram. Although a flowchart may describe the operations as a sequential process, many of the operations can be performed in parallel or concurrently. In addition, the order of the operations may be re-arranged. A process is terminated when its operations are completed.

In the following, further examples are described to facilitate the understanding of the invention.

Aspect 1: A substrate comprising at least one dielectric layer; a plurality of interconnects comprising a first plurality of trace interconnects located on a first metal layer of the substrate, wherein the first plurality of trace interconnects are configured as one or more coils of a first inductor; and a second plurality of trace interconnects located on a second metal layer of the substrate, wherein the first plurality of trace interconnects are configured as one or more coils of a second inductor; at least one cavity in the at least one dielectric layer; and a solder resist layer located at least partially in the at least one cavity in the at least one dielectric layer.

Aspect 2: The substrate of aspect 1, where the solder resist layer is a different material from the at least one dielectric layer.

Aspect 3: The substrate of aspects 1 through 2, wherein the at least one cavity has a minimum width of 35 micrometers.

Aspect 4: The substrate of aspects 1 through 3, wherein the at least one cavity extend beyond the first metal layer and the second metal layer of the substrate.

Aspect 5: The substrate of aspects 1 through 4, wherein the first inductor includes a first minimum spacing between two adjacent trace interconnects of the first inductor, wherein the first minimum spacing is 35 micrometers.

Aspect 6: The substrate of aspect 5, wherein the second inductor includes a second minimum spacing between two adjacent trace interconnects of the second inductor, wherein the second minimum spacing is 35 micrometers.

Aspect 7: The substrate of aspects 1 through 6, further comprising a minimum horizontal spacing between a trace interconnect on the first metal layer from the first inductor and a trace interconnect on the second metal layer from the second inductor, wherein the minimum horizontal spacing is 35 micrometers.

Aspect 8: A substrate comprising at least one dielectric layer; a plurality of interconnects comprising a first plurality of trace interconnects located on a first metal layer of the substrate, wherein the first plurality of trace interconnects are configured as one or more coils of a first inductor; and a second plurality of trace interconnects located on a second metal layer of the substrate, wherein the first plurality of trace interconnects are configured as one or more coils of a second inductor; at least one cavity in the at least one dielectric layer; and another dielectric layer located at least partially in the at least one cavity in the at least one dielectric layer.

Aspect 9: The substrate of aspect 8, where the another dielectric layer is a different material from the at least one dielectric layer.

Aspect 10: The substrate of aspect 8, where the another dielectric layer is a same material as the at least one dielectric layer.

Aspect 11: The substrate of aspects 8 through 10, wherein the at least one cavity has a minimum width of 35 micrometers.

Aspect 12: The substrate of aspects 8 through 11, wherein the at least one cavity extend beyond the first metal layer and the second metal layer of the substrate.

Aspect 13: The substrate of aspects 8 through 12, wherein the another dielectric layer comprises epoxy.

Aspect 14: The substrate of aspect 13, wherein the at least one dielectric layer comprises prepreg.

Aspect 15: The substrate of aspects 8 through 14, further comprising a solder resist layer coupled to the another dielectric layer.

Aspect 16: The substrate of aspects 8 through 15, wherein the plurality of interconnects are located in the at least one dielectric layer and the another dielectric layer.

Aspect 17: The substrate of aspect 16, wherein the first metal layer is a M2 metal layer of the substrate and the second metal layer is a M3 metal layer of the substrate.

Aspect 18: The substrate of aspects 8 through 17, wherein the first metal layer is a M1 metal layer of the substrate and the second metal layer is a M2 metal layer of the substrate.

Aspect 19: The substrate of aspects 8 through 18, wherein a first edge of a first trace interconnect from the first inductor vertically aligns with a first edge of a first trace interconnect from the second inductor, wherein a second edge of a second trace interconnect from the first inductor vertically aligns with a second edge of a second trace interconnect from the second inductor, and wherein a third edge of a third trace interconnect from the first inductor vertically aligns with a third edge of a third trace interconnect from the second inductor.

Aspect 20: The substrate of aspects 8 through 19, wherein the first inductor includes a first minimum spacing between two adjacent trace interconnects of the first inductor, wherein the first minimum spacing is 35 micrometers.

Aspect 21: The substrate of aspects 1 through 20, wherein the substrate is implemented in a device selected from a group consisting of a music player, a video player, an entertainment unit, a navigation device, a communications device, a mobile device, a mobile phone, a smartphone, a personal digital assistant, a fixed location terminal, a tablet computer, a computer, a wearable device, a laptop computer, a server, an internet of things (IoT) device, and a device in an automotive vehicle.

The various features of the disclosure described herein can be implemented in different systems without departing from the disclosure. It should be noted that the foregoing aspects of the disclosure are merely examples and are not to be construed as limiting the disclosure. The description of the aspects of the present disclosure is intended to be illustrative, and not to limit the scope of the claims. As such, the present teachings can be readily applied to other types of apparatuses and many alternatives, modifications, and variations will be apparent to those skilled in the art.

1. A substrate comprising:
at least one dielectric layer;
a plurality of interconnects comprising:
a first plurality of trace interconnects located on a first metal layer of the substrate, wherein the first plurality of trace interconnects are configured as one or more coils of a first inductor; and
a second plurality of trace interconnects located on a second metal layer of the substrate, wherein the first plurality of trace interconnects are configured as one or more coils of a second inductor;
at least one cavity in the at least one dielectric layer; and
a solder resist layer located at least partially in the at least one cavity in the at least one dielectric layer.

2. The substrate of claim 1, where the solder resist layer is a different material from the at least one dielectric layer.

3. The substrate of claim 1, wherein the at least one cavity has a minimum width of 35 micrometers.

4. The substrate of claim 1, wherein the at least one cavity extend beyond the first metal layer and the second metal layer of the substrate.

5. The substrate of claim 1, wherein the first inductor includes a first minimum spacing between two adjacent trace interconnects of the first inductor, wherein the first minimum spacing is 35 micrometers.

6. The substrate of claim 5, wherein the second inductor includes a second minimum spacing between two adjacent trace interconnects of the second inductor, wherein the second minimum spacing is 35 micrometers.

7. The substrate of claim 1, further comprising a minimum horizontal spacing between a trace interconnect on the first metal layer from the first inductor and a trace interconnect on the second metal layer from the second inductor, wherein the minimum horizontal spacing is 35 micrometers.

8. A substrate comprising:
at least one dielectric layer;
a plurality of interconnects comprising:
a first plurality of trace interconnects located on a first metal layer of the substrate, wherein the first plurality of trace interconnects are configured as one or more coils of a first inductor; and
a second plurality of trace interconnects located on a second metal layer of the substrate, wherein the first plurality of trace interconnects are configured as one or more coils of a second inductor;
at least one cavity in the at least one dielectric layer; and
another dielectric layer located at least partially in the at least one cavity in the at least one dielectric layer.

9. The substrate of claim 8, where the another dielectric layer is a different material from the at least one dielectric layer.

10. The substrate of claim 8, where the another dielectric layer is a same material as the at least one dielectric layer.

11. The substrate of claim 8, wherein the at least one cavity has a minimum width of 35 micrometers.

12. The substrate of claim 8, wherein the at least one cavity extend beyond the first metal layer and the second metal layer of the substrate.

13. The substrate of claim 8, wherein the another dielectric layer comprises epoxy.

14. The substrate of claim 13, wherein the at least one dielectric layer comprises prepreg.

15. The substrate of claim 8, further comprising a solder resist layer coupled to the another dielectric layer.

16. The substrate of claim 8, wherein the plurality of interconnects are located in the at least one dielectric layer and the another dielectric layer.

17. The substrate of claim 16, wherein the first metal layer is a M2 metal layer of the substrate and the second metal layer is a M3 metal layer of the substrate.

18. The substrate of claim 8, wherein the first metal layer is a M1 metal layer of the substrate and the second metal layer is a M2 metal layer of the substrate.

19. The substrate of claim 8,
wherein a first edge of a first trace interconnect from the first inductor vertically aligns with a first edge of a first trace interconnect from the second inductor,
wherein a second edge of a second trace interconnect from the first inductor vertically aligns with a second edge of a second trace interconnect from the second inductor, and
wherein a third edge of a third trace interconnect from the first inductor vertically aligns with a third edge of a third trace interconnect from the second inductor.

20. The substrate of claim 8, wherein the first inductor includes a first minimum spacing between two adjacent trace interconnects of the first inductor, wherein the first minimum spacing is 35 micrometers.
